(19) United States
(12) Patent Application Publication
(10) Pub. No.: US 2012/0305077 A1
(43) Pub. Date: Dec. 6, 2012

(54) CONCENTRATED PHOTOVOLTAIC AND THERMAL SYSTEM

(75) Inventors: Ra'ed Arab, Ottawa (CA); Yousef Awad, Ottawa (CA); Mihai Grumazescu, Nepean (CA)

(73) Assignee: QUADRA SOLAR CORPORATION, Ottawa, ON (CA)

(21) Appl. No.: 13/578,331

(22) PCT Filed: Feb. 10, 2011
(86) PCT No.: PCT/CA2011/000150

§ 371 Date: Aug. 10, 2012

(30) Foreign Application Priority Data
Feb. 10, 2010 (CA) 2690162

(51) Int. Cl. H01L 31/0232; H01L 31/0203

(52) U.S. Cl. 136/259

(57) ABSTRACT

A concentrated photovoltaic and thermal system is disclosed. The system compromises a photovoltaic receiver assembly that produces highly concentrated solar energy, resulting in efficient energy conversion that requires fewer photovoltaic receivers than an arrangement that lacks such high concentration levels. The receiver assembly comprises a primary optical element that concentrates the source light onto an electromagnetic energy receiver, a secondary optical element to aid in further concentration of the light source, a thermal energy converter and a heat dissipation unit. The photovoltaic receiver assembly is preferably mounted on a tracking system to maximize sun exposure.

### TECHNICAL FIELD

The application relates to a photovoltaic and thermal concentrator system. More specifically, the application relates to a photovoltaic receiver assembly comprising an optical element that concentrates the source light onto the receiver, a secondary optics element, and a heat dissipation system.

### BACKGROUND

Concentrated photovoltaic (CPV) systems generally focus a large amount of sunlight onto a small area of photovoltaic cells to generate electricity. This concentration of sunlight typically increases the efficiency of electricity generation, which allows for reduced size and cost of the system, when compared to more conventional photovoltaic systems. Accordingly, there are ongoing developments in the field of high efficiency CPV systems in an attempt to achieve grid parity. Such developments include improvements in solar cells, optical elements, and tracking systems.

In order to concentrate incident radiation, CPV systems require an optical system. This optical system is generally composed of lenses, mirrors, or a combination of both. The materials of such optical systems are significantly cheaper than the photovoltaic materials that they replace. Optical systems may be simple or consisting of primary and secondary optical elements. A wide array of optical elements are currently being developed and implemented at different scales, such as circular parabolic dishes; parabolic dishes with secondary optical elements; square flat Fresnel lenses; square flat Fresnel lenses with secondary optical elements; linear flat lenses; linear arched lenses; and finally linear parabolic reflectors.

Reflective components are generally employed on low concentration CPV systems, for example plane mirrors, parabolic dishes or V-though mirrors. For medium and high concentration CPV systems, the most implemented optical elements are the refractive devices based on Fresnel lenses, which either apply simple refraction or secondary optics. Some high-efficiency CPV systems are fitted with reflective optics elements as well, although most of the systems currently designed employ Fresnel lenses as the primary optical element. A Fresnel lens is a special type of lens that reduces the amount of material required to concentrate the light, by splitting the lens into a set of concentric annular sections known as Fresnel zones. The use of these zones allows keeping the required curvature without increasing the thickness, by means of adding discontinuities between them. An important reduction in thickness can be achieved, but the imaging quality of the lens is reduced. This is commonly known as non-imaging optics.

The acceptance angle of a CPV system is barely a few times the angle subtended by the sun and its impact is often underestimated: wide acceptance angles can greatly reduce assembly and alignment requirements. The acceptance angle is also dramatically important in field installation, where alignment and assembly of different modules in the tracker can become very difficult if the acceptance angle is very narrow. Tracker stiffness and performance are also enormously influenced by the acceptance angle. Wider acceptance angles allow less stiff trackers which translate into less material-intensive trackers and, as a consequence, cheaper ones. Because tracker cost is an important factor in system total cost, the cost/Watt-peak figure can be significantly reduced by increasing the acceptance angle. In addition, the acceptance angle has a great impact in annual energy generation, so it is directly related to the cost of Kilowatt-hour of electricity generated. That is, it can affect whether the energy generated by the CPV system is competitive or not, and therefore, whether the system is financially feasible.

Another potential consequence related to the optical system is that the irradiance distribution over the photovoltaic cell is not always uniform. Many designs of optical systems lead to irradiance peaks, as opposed to uniform irradiance, over the cell. This lack of irradiance uniformity can put long term reliability of the cell at a risk. Concentration peaks can cause thermal stresses which could damage the cell. In addition, it has not yet been shown what maximum local current density can be handled by a tunnel diode in a multi junction cell. Moreover, lack of uniformity can increase the effective series resistance and decrease the Fill Factor. Concentration peaks are addressed by increasing the acceptance angle and/or equalizing irradiance over the cell. This solution often requires the use of a Secondary Optical Element (SOE) in addition to the Primary Optical Element (POE), which can help to stabilize and disperse the light source rays Energy generation enhancement often overcomes the cost of adding an additional optical element to the system. Although some different designs that do not incorporate an SOE, most of the CPV systems in the market include an SOE.

A well designed secondary optical element can provide benefits, such as keeping cell irradiance uniform, and improving the overall acceptance angle of energy arriving at the collector. Secondary optical elements are typically solid glass or dielectric optics that are ground and polished or moulded into a desired shape and then placed above the active surface of the solar cell.

There is considerable interest in tracking the sun with a solar collector, as tracking the sun can provide approximately 40% more power when compared to stationary panels having the same number of solar cells. Current solar tracking systems are relatively large and many are mounted on vertical poles that can extend several meters into the air. This type of tracker suffers from many limitations, which can constrain installation on most residential and commercial rooftops. These limitations include heavy load, non-distributed load, exposure of the panel areas to high wind load, and creation of shading on adjacent panels. Furthermore, to enable tracking when the sun is at a low elevation angle, the panels must be tilted almost to a vertical position; such tilting increases the vertical distance the system occupies which may be considered a violation of many cities' regulations.

The prior art contains examples of CPV systems. The following is a non-exhaustive list of such examples.

U.S. Pat. No. 4,710,588 discloses a photovoltaic-thermoelectric solar cell where the magnitude of the thermoelectric voltage contribution is increased by reducing the coefficient of thermal conductivity of the solar cell material. This is accomplished by using face electrodes having the proper thermoelectric potentials in contact with the solar cell material, increasing the light intensity and then the heat input to the front side of the solar cell, and by cooling the back side of the solar cell.

United States Patent Publication No. 20070215198 discloses a thermally managed solar cell system, which includes a photovoltaic cell for generating electricity and heat. The system includes a housing, a base, and a heat removal device. The housing surrounds the solar cell system and has an open, rear portion. The base is positionable in the open portion of the housing and supports the photovoltaic cell. The base is also thermally conductive and spreads heat generated from the photovoltaic cell. The heat removal device and the base act as a single unit with the heat removal device being coupled to the base to remove the heat from the base.

United States Patent Publication No. 20090194146 discloses a method and apparatus for arranging multiple flat reflector facets around a solar cell or solar panel comprising multiple reflector facets arranged to form an inverted pyramid shell, where the apex of the pyramid is removed and replaced by a solar cell or panel. Alternatively, this may be done with only three reflective facets.

U.S. Pat. No. 7,569,764 discloses solar modules with tracking and concentrating features, comprising one or more solar concentrator assemblies having a solar tracking capability. For example, the assemblies can include an array of photovoltaic receivers and/or thermoelectric receivers, one or more optical concentrators configured to reflect and/or refract solar radiation onto the array of receivers when aperture normals of the concentrators are aligned with the sun, and a tracking mechanism for maintaining alignment of the aperture normals with the sun by at least once daily alignment adjustments to account for seasonal variations in angle of incidence of solar radiation.

United States Patent Publication No. 20100275902 discloses a photovoltaic and thermal energy system. The system concentrates sunlight on solar cells using refractive or reflective optics, and by employing a simple clock motor to track the sun from sunrise to sunset in a diurnal tracking mode. The increased heat generated by the concentration of the sun's insolation on the reduced number of solar cells is drawn off by an anti-freeze fluid circulated in an aluminum extrusion to which the solar cells and the concentrator reflective or refractive optics are attached. Preferably, the optical components of the photovoltaic system employ plano mirrors as reflective side panels and a cylindrical Fresnel lens to focus the sunlight on the solar cells.

United States Patent Publication No. 20080041441 discloses a solar concentrator device for photovoltaic energy generation, which comprises a prism array. Each prism is designed to deflect the incident solar rays and fully illuminate a rectangular photovoltaic cell with uniform intensity. The combination of multiple prisms uniformly illuminating a common target area yields concentrated uniform illumination across the target area. A heat sink is also provided to help dissipate excess energy generated by the photo cell.

### SUMMARY

According to an aspect of the concentrated photovoltaic and thermal system, there is provided a concentrated photovoltaic solar collector system comprising at least one concentrated photovoltaic receiver assembly, and a sun tracking system that provides support and movement to at least one concentrated photovoltaic receiver assembly.

The concentrated photovoltaic receiver assembly comprises a concentrated photovoltaic solar collector, a thermal conversion device in thermal communication with the solar cell, and a cooling unit in thermal communication with the thermal conversion device and/or the solar cell.

The concentrated photovoltaic solar collector comprises a housing having an upper opening and a lower opening, where the lower opening is narrower than the upper opening, a solar cell positioned at the lower opening of the housing, a primary optical element positioned proximate to the upper opening of the housing, and a secondary optical element positioned inside the housing and proximate to the lower opening. The primary optical element and the secondary optical element are shaped, dimensioned and positioned to direct and concentrate light source rays into the housing and onto the solar cell.

The sun tracking system comprising a base, a platform adapted to receive at least one concentrated photovoltaic receiver assembly, and a plurality of linear actuators movably connecting the platform to the base. The plurality of linear actuators extend and retract to tilt the platform.

### BRIEF DESCRIPTION OF THE DRAWINGS

The concentrated photovoltaic and thermal system will now be described in more detail with regard to the Drawings, in which:

FIG. 1 is a perspective view of an embodiment of the concentrated photovoltaic and thermal system;

FIG. 2 is a perspective view of an individual solar collector as shown in FIG. 1;

FIG. 3 is a side view of the individual solar collector as shown in FIG. 2;

FIG. 4 is a side view of a secondary optical element according to one embodiment of the concentrated photovoltaic and thermal system;

FIG. 5 is a side cutaway view of a thermionic converter utilized in one embodiment of the concentrated photovoltaic and thermal system;

FIG. 6 is a side cutaway view of the lower portion of a photovoltaic receiver assembly, according to one embodiment of the concentrated photovoltaic and thermal system;

FIG. 7 is a side cutaway view of the lower portion of a photovoltaic receiver assembly, according to one embodiment of the concentrated photovoltaic and thermal system;

FIG. 8 is a side cutaway view of a cooling unit used to cool a photovoltaic receiver assembly, according to one embodiment of the concentrated photovoltaic and thermal system;

FIG. 9 is a perspective view of a sun tracking system employing three actuators, according to one embodiment of the concentrated photovoltaic and thermal system;

FIG. 10 is a perspective view of a sun tracking system employing two actuators, according to one embodiment of the concentrated photovoltaic and thermal system;

FIG. 11 is a perspective view of a sun tracking system employing two actuators, according to one embodiment of the concentrated photovoltaic and thermal system;

FIG. 12 is a perspective view of an embodiment of the concentrated photovoltaic and thermal system;

FIG. 13 is a side view of an embodiment of the concentrated photovoltaic and thermal system while in the horizontal position;

FIG. 14 is a side view of the concentrated photovoltaic and thermal system shown in FIG. 13, while in a tilted, or tilted and raised position;

FIG. 15 is a side view of pairs of solar collectors in various stages of tilt, illustrating the level of shading that occurs between adjacent solar collectors.

### DETAILED DESCRIPTION

A better understanding of the concentrated photovoltaic and thermal system and its objects and advantages will become apparent to those skilled in this art from the following detailed description, in which are described preferred embodiments, simply by way of illustration only. As will be realized, the concentrated photovoltaic and thermal system is capable of modifications in various obvious respects, all without departing from the scope thereof. Accordingly, the description should be regarded as illustrative in nature and not as restrictive.

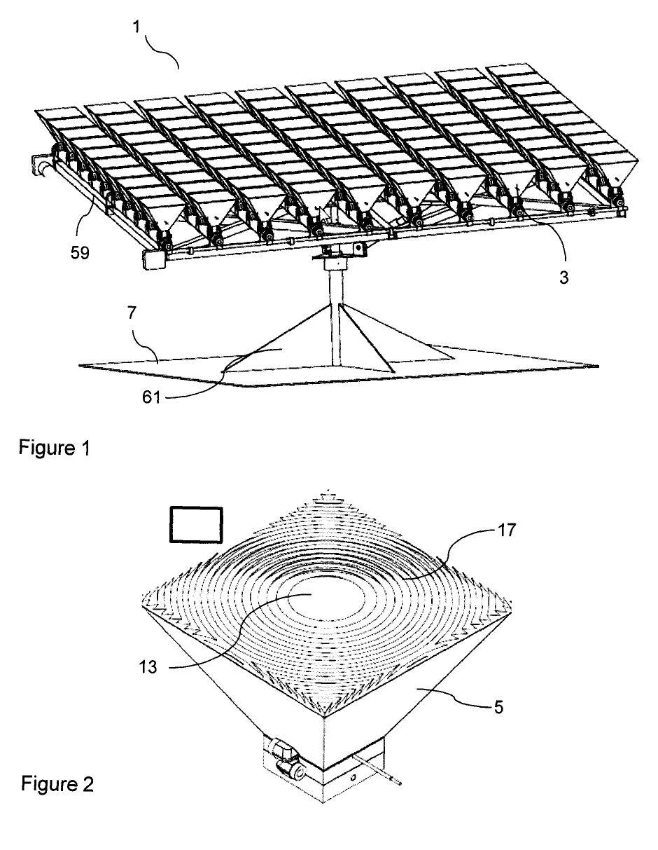

FIG. 1 illustrates a concentrated photovoltaic and thermal (CPVT) system 1, comprising an assembly of photovoltaic receiver assemblies 3 mounted on a tracking system 7.

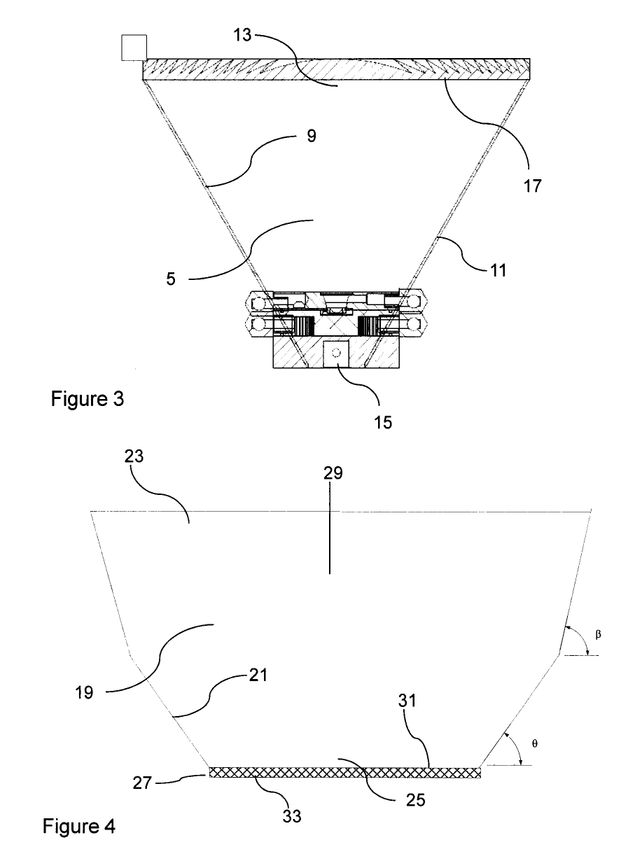

Referring to FIGS. 2 and 3, a photovoltaic receiver assembly 3 comprises, a solar collector 5. solar collector 5 is primarily purposed to collect, concentrate and direct solar rays 18 (shown in FIG. 6). The solar collector 5 is preferably made of plastic, glass, metal or other sturdy rigid material that provides support to the collector 5 when it tilts and under windy conditions. Although in an alternative embodiment, the solar collector 5 is made of a non-rigid material, such as balloon or film, and therefore the height of the solar collector 5 is sufficient to maintain the solar collector's 5 shape. In order to effectively direct and concentrate light source rays 18 (as shown in FIG. 6), it is preferred that the inner walls 9 of the solar collector 5 are made of, or coated with, a highly reflective, mirror-like material. According to one embodiment, the solar collector 5 has an upper opening 13 and a lower opening 15, and is in the form of an inverted symmetrical, truncated, pyramid, defining a square aperture at its top. However, other shapes of the housing are contemplated, such as, but not limited to, frusto-conical or parabolic. It is preferred that the solar collector 5 has a relatively wide upper opening 13 in order to increase acceptance of light source rays 18. It is also contemplated that the outer surface 11 of the solar collector 5 is coated with a material, such as a reflective material, that is able to dissipate excess heat, specifically that which is not captured within the collector 5, in order to prevent damage to the collector 5 resulting from overheating.

According to an embodiment, at least a portion of the upper opening 13 at the top of the solar collector 5 comprises a primary optical element (POE) 17. The POE 17 is purposed to concentrate and/or focus the light source rays 18 within the solar collector 5. As shown in FIGS. 2 and 3, the POE 17 may be a Fresn el lens, although other additional optical elements, such as a concave lens or other light capturing lenses may be used in the solar collector 5. The POE 17 may sit atop and encase the upper opening 13 of the solar collector 5, but may also be recessed within the upper opening 13 of the solar collector 5.

The CPVT system 1 is typically positioned outside, such as on rooftops, and therefore, each solar collector 5 is preferably designed and configured to be substantially resistant to the elements. For example, the solar collector 5 creates a weather proof enclosure by having water-tight joints and seals, or alternatively, the housing of the solar collector 5 is coated with a protective cover, such as a membrane. Configured in this manner, the solar collector 5 will have increased longevity, and any internal components of the solar collector 5, such as a secondary optical element 19 (shown in FIG. 4) or an electromagnetic energy receiver 27 (shown in FIG. 4), will be shielded from the elements.

According to an embodiment, the solar collector 5 comprises a secondary optical element 19. Referring to FIG. 6, a secondary optical element (SOE) 19 receives light source rays 18 and further optimizes the concentration and redirection of the source light rays 18. This will have the effect of increasing the acceptance angle of the source light rays 18. In this embodiment, the SOE 19 may receive the light source rays 18 directly from the light source, directly from the POE 17, or after they have been reflected and redirected from the interior surface 9 of the solar collector 5. The SOE 19 is located within the solar collector 5, and more specifically, is typically located near the lower portion thereof proximate the electromagnetic energy receiver 27, in order to direct the light source rays 18 onto the electromagnetic energy receiver 27.

An exemplary SOE 19 is illustrated in FIG. 4. In this embodiment, the SOE 19 comprises a hollow structure having an interior surface 21, and defining both an entry aperture 23 and an exit aperture 25. The SOE 19 may be an insert that is placed within the housing of the solar collector 5. Alternatively, the SOE 19 may be integral to the housing of the solar collector 5, such that the lower portion of the housing is shaped and dimensioned according to the requirements of the SOE 19. The interior surface 21 of the SOE 19 receives concentrated light source rays 18 (shown in FIG. 6) that are to be propagated and directed toward the electromagnetic energy receiver 27, and therefore, at least a portion of the interior surface 21 of the SOE 19 is reflective. The reflective surface preferably has a smooth and polished mirror-like finish, such that it is able to reliably reflect received light source rays 18. The interior side surfaces 21 may optionally be polished, anodized, or otherwise coated or treated so as to enhance the degree of optical reflection. The reflected light source rays 18 are ultimately directed and focused at an electromagnetic energy receiver 27.

The exact structure, design, shape and size of the SOE 19 should not be considered limiting, and will be based upon a variety of factors, such as the POE 17, the shape of the solar collector 5 and the angle of acceptance of the light source. Based on these factors, the SOE 19 is designed to further reflect and direct the light source rays 18 (shown in FIG. 6) onto the electromagnetic energy receiver 27. For example, the SOE 19 may be narrower at the lower portion, as opposed to the upper portion, where the upper portion is the portion that comprises the entry aperture 23 and is closest to incident electromagnetic energy. The entry aperture 23 may be formed such that the width thereof is larger than the beam width of concentrated light source rays 18 transmitted from the POE 17. The exit aperture 25 may be sized such that it is slightly larger than at least a portion of the top surface 31 of the one or more electromagnetic energy receivers. The converging side surfaces 21 may be provided with any suitable geometry or configuration. According to non-limiting examples, the converging side surfaces 21 of the SOE 19 can be cup-shaped, frusto-conical, or in the form of a regular or irregular polygonal frustum. The slope of the side surfaces 21 of the SOE 19 may all be the same, or may differ relative to each other. In particular, the SOE 19 may have a plurality of side surfaces 21, where each side surface 21 has a different slope, such as in the SOE 19 illustrated in FIG. 4. The angles θ and β in FIG. 4, which respectively determine the slope of the two side surfaces 21 in this example, may vary, and are determined to maximize the redirection and concentration of the light source rays on the electromagnetic energy receiver 27. According to further non-limiting examples, one or more of the side surfaces 21 may take the form of a curved shape, an irregular polygon, a triangle, a rectangle, a square, a trapezoid or other polygon.

According to an alternative embodiment, an optical material, i.e. a material capable of transmitting light source rays 18, which has an index of refraction greater than air, is provided in the SOE 19 between the entry 23 and exit 25 apertures. The optical material will redirect light source rays 18 that enter the middle portion 29 of the SOE 19. The thickness of the optical material is not limiting, and the optical material may span the entire SOE 19 from the entry aperture 23 to the exit aperture 25, but may also be a thin layer. The optical material may comprise one or more of: plastic, acrylic material, quartz, glass, metal, semiconductor material, films and fluid-filled structures.

An electromagnetic energy receiver 27, such as a solar or photovoltaic cell, is positioned near the base of the solar collector 5. The receiver 27 has a top surface 31, which is exposed to the interior of the solar collector 5, and a bottom surface 33. Preferably, the receiver 27 is proximate to the exit aperture 25 of the SOE 19, in order to minimize the distance the light source rays 18 are required to travel from the SOE 19. The receiver 27 is preferably a solar or photovoltaic cell, as would be known to one of skill in the art, and is capable of converting light source rays 18, e.g. solar energy, into electricity. The light source rays 18 from the solar collector 5 is reflected and directed through the exit aperture 25 of the SOE 19, and are thereby concentrated on the electromagnetic energy receiver 27. The receiver 27 is able to transform the concentrated light source rays 18 into electricity that is harnessed by the CPV system 1.

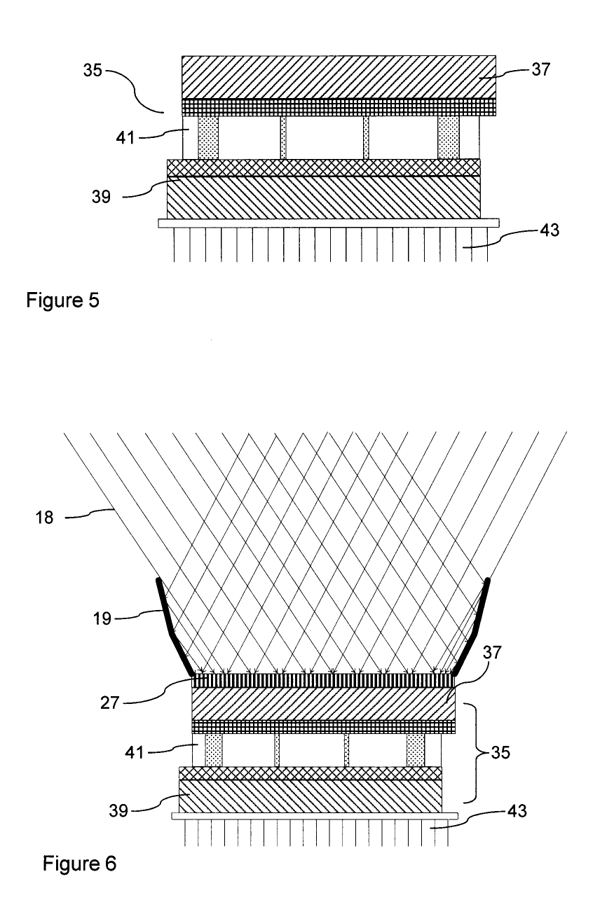

According to one embodiment, the photovoltaic receiver assembly 3 comprises a thermal conversion device 35, as shown in FIG. 5. The thermal conversion device 35 captures thermal energy from the light source rays 18 and converts it into electricity. The thermal conversion device 35 is in thermal communication with the solar collector 5, and in particular, with the electromagnetic energy receiver 27. For example, the thermal conversion device 35 may be a thermionic converter, as known in the art.

An exemplary thermal conversion device 35 is shown in FIGS. 5 and 6. Typically, the thermionic converter 35 is a sandwiched structure comprising two electrodes 37 and 39: the hot electrode (cathode) 37 located just below the electromagnetic receiver 27, and a cold electrode (anode) 39. The two electrodes 37 and 39 are separated by a spacer or inter-electrode gap 41. The heat generated from the concentrated light source rays 18 onto the electromagnetic energy receiver 27 is used as the heat source for the thermionic converter 35. Electrons effectively “boil off” the hot electrode 37, cross the gap 41, and condense on the cold electrode 39, where they produce a voltage that drives a current.

The hot electrode 37 can be made of any low electron-work function metals including but not limited to Ir, Pt, Au, Re, Mo or those metals having a work function of 3-5 eV. Alternatively, the hot electrode 37 may be made of a high-IR emissivity metals such as metal carbides, Co and Ni. Optionally, the cold electrode 39 can be made of high IR reflectivity metals such as, but not limited to, Al, Cu, Ag and Au. Also, the spacer material preferably comprises highly electrically and thermally insulating materials, such as, but not limited to, TiO₂.

The electric current generated from the thermionic converter is given by Dushmann's Equation:

$${I}_{0} = {AT}^{2} {e}^{- \frac{11600 w}{T}}$$

where:
I₀=emitted current
A=a constant, 120.4 A/cm²
T=temperature expressed in K
w=work function of emitting metal
e=2.71828 . . . .

As seen from the above equation, the emitted current increases rapidly with temperature.

According to another embodiment, the photovoltaic receiver assembly 3 comprises a cooling unit or heat sink 43. It is preferable that the cooling unit 43 is in communication with the thermal conversion device 35. Cooling the thermal conversion device 35 will increase the overall efficiency of the thermal conversion device 35 by minimizing any back emission of electrons. In an alternative embodiment, the cooling unit 43 is in communication with the electromagnetic energy receiver 27. When the light source rays 18 are concentrated and directed across the electromagnetic energy receiver 27, extreme temperatures can be reached. Accordingly, it is desirable to keep the electromagnetic energy receiver 27 below a threshold temperature in order to increase its longevity and performance.

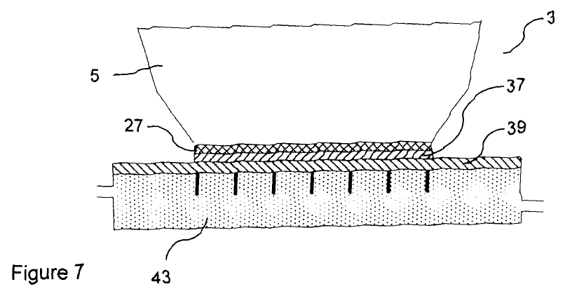

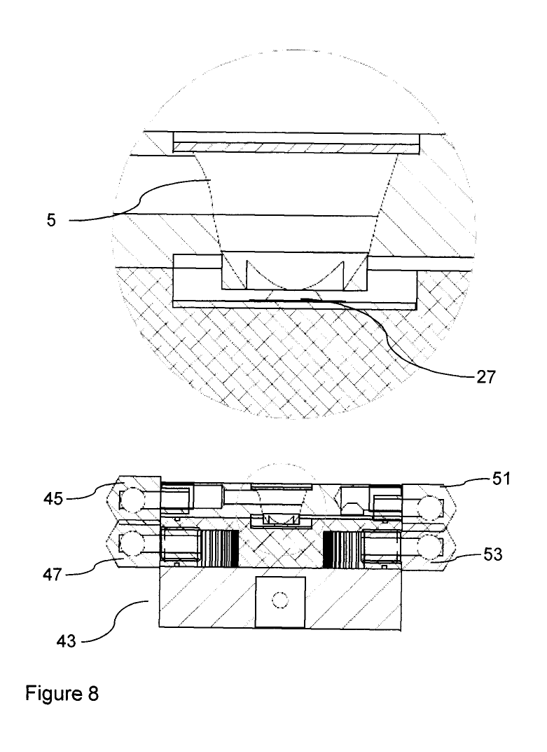

The exact nature of the cooling unit 43 is not limiting, and a cooling unit 43 known to one of skill in the art can be incorporated into the solar collector 5. According to another embodiment, the system 1 incorporates an exemplary cooling unit 43 as illustrated in FIGS. 6 to 8, where the electromagnetic energy receiver 27 and thermionic converter 35 are mounted on top of the cooling unit 43. In an exemplary cooling unit 43, cooling liquid or coolant circulates below and/or above the electromagnetic energy receiver 27. The cooling liquid may be any glycol based liquid, such as antifreeze liquid.

In an exemplary cooling unit 43, the coolant is supplied by top 45 and bottom 47 inlet hoses. Connecting pipes 49 then transfer the coolant to the interior of the cooling unit 43 where it interacts with the thermal conversion device 35 and/or the electromagnetic energy receiver 27. The circulating cooling fluid is then removed from the cooling unit 43 by a series of outlet pipes and hoses 51 and 53. The removed coolant is cooled using a variety of known methods, such as an adsorption unit or an external air radiator, and is then recirculated through the cooling unit 43. The cooling unit 43 also comprises a control valve, which secures unidirectional movement of heated liquid away from the electromagnetic energy receiver 27 and/or thermal conversion device 35. A small pump can be added to accelerate circulation of cooling liquid into and out of the cooling unit.

According to one embodiment of the cooling unit 43, the top layer 31 of the electromagnetic energy receiver 27 is cooled. In this embodiment, the top layer 31 of the receiver 27 is covered with a coolant by immersing the receiver 27. The coolant is injected through a top inlet 45 and exits through a top outlet 51. Furthermore, in this embodiment, heat can be transferred from both the top 31 and bottom 33 receiver surfaces. The liquid can be any dielectric coolant that has amongst the following properties: good thermal conductivity, low viscosity; long-term chemical and physical stability; low optical absorption; good optical stability, non-toxic, and cost effective.

According to another embodiment, at least one concentrated photovoltaic receiver assembly 3 is mounted on a sun tracking system 7 as illustrated in FIG. 1. A tracking system 7 allows the concentrated photovoltaic receiver assembly 3 to follow the movement of the sun throughout the day, optimizing the generation of electricity from solar energy. The concentrated photovoltaic receiver assemblies 3 are preferably mounted on the sun tracking system 7 in a hinged manner, such that they are able to rotate about the sun tracking system platform 59, however, they may also be statically mounted. In one embodiment, movement of each concentrated photovoltaic receiver assembly 3 is controlled by, e.g. a motor 69, to provide additional tracking capabilities.

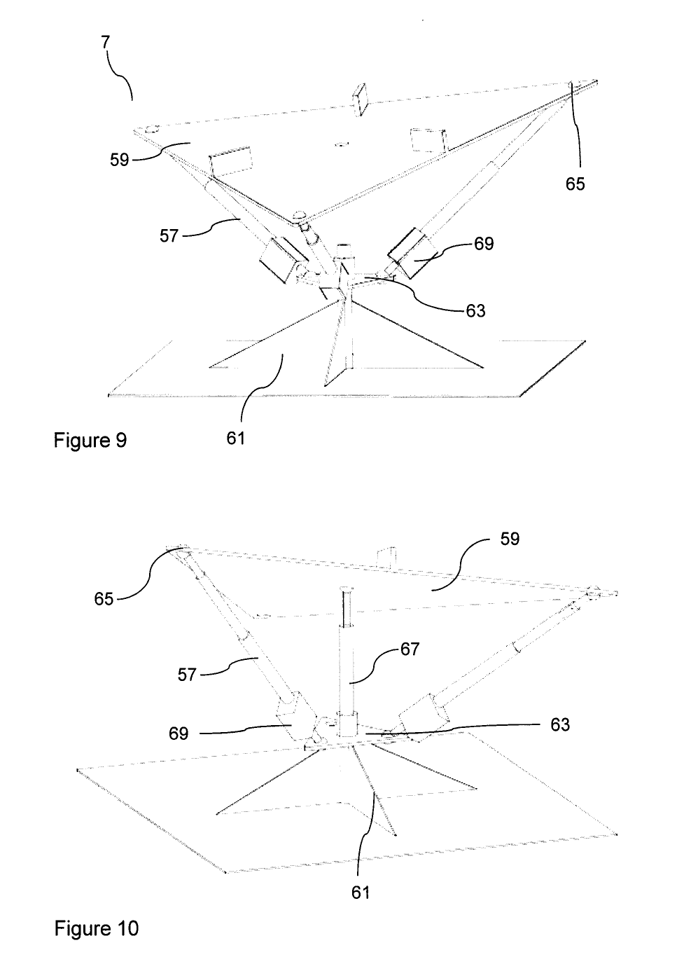

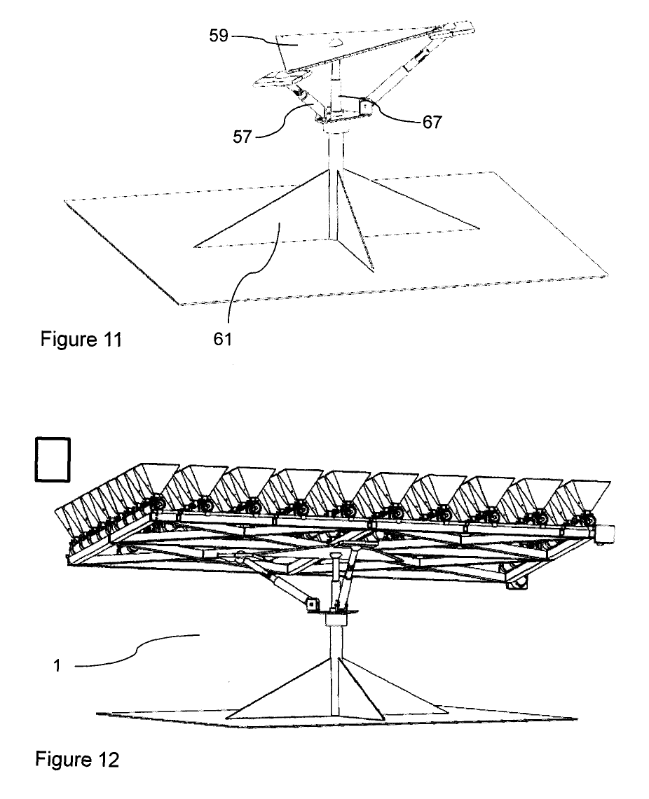

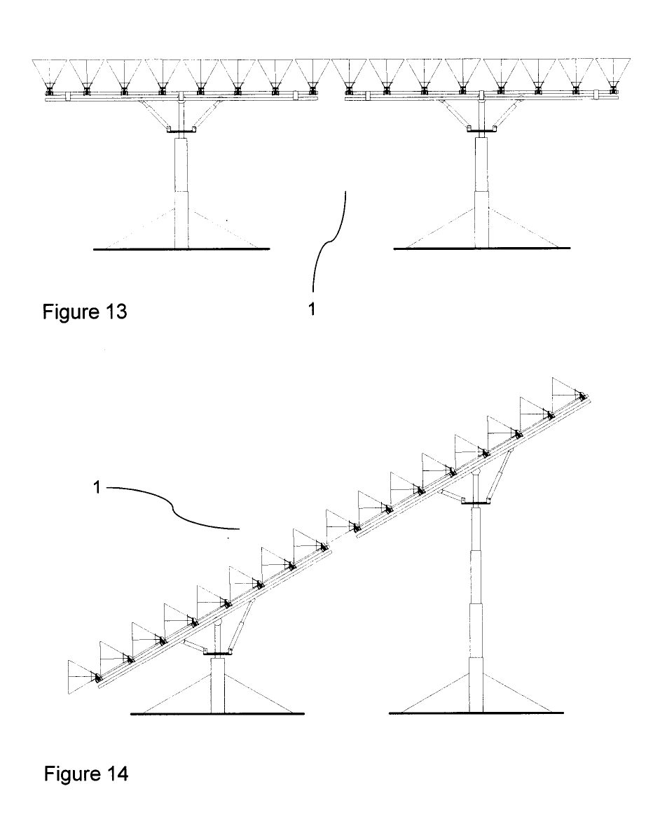

The concentrated photovoltaic receiver assembly 3 may be mounted onto any known sun tracking system 7, however, according to one embodiment, a sun tracking system 7 as shown in any of FIGS. 9 to 14 is utilized. This sun tracking system 7 is non-rotating, but rather is capable of tilting in all directions to follow the sun The sun tracking system 7 comprises linear actuators 57 that movably connect a platform 59 to a base 61. Optionally, a platform support 63 can be mounted on the base 61, and the platform 59 can be movably connected to the platform support 63. The actuators 57 may be connected to the platform 59 and/or base 61 with spherical joints 65, which will provide rotational capabilities to the system 7. Through the use of these actuators 57, i.e. controlling the length of the linear actuators 57, the tracking system 7 is capable of tilting in all directions to assume a wide array of positions, and thereby effectively track the sun.

The shape of the platform 59 is not limiting, and may be triangular, as shown in FIG. 9, however, other shapes may also be employed. The number of actuators 57 in the tracking system 7 as well as their connection point to the platform 59 is typically dictated by the shape of the platform 59. For example, with a triangular platform 59, three actuators 57 connecting to each of the vertices is preferable, although any number of actuators 57 may be employed provided that a wide range of motion is possible. Additionally, the tracking system 7 may have a support 67 centrally located between the base 61 and the platform 59 to mitigate the weight load of the CPVT system 1. The support 67 may also be an actuator capable of raising and lowering the platform 59, which will allow adjacent CPVT systems 1 to be tiered vertically (see FIG. 14).

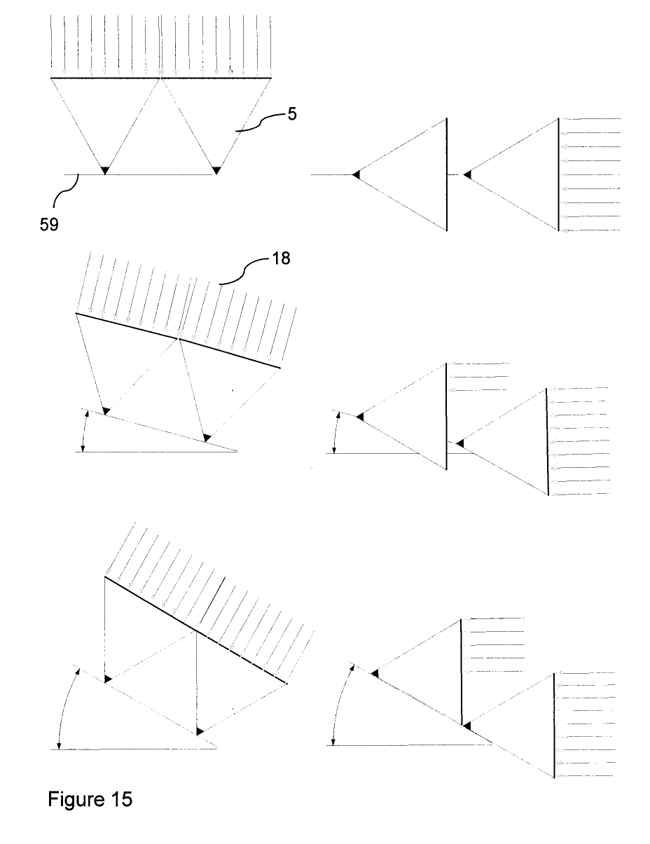

Typically, solar collectors 5 shadow each other at low sun angles, thereby decreasing energy capture. FIG. 15 illustrates two exemplary concentrated photovoltaic receiver assemblies 3 mounted to the tilting sun tracking system 7 as described above, where it is illustrated that tilt angles of both the solar collectors 5 and the sun tracking system 7 reduces this shadowing effect.

According to another embodiment, the electromagnetic energy receiver 27 can be replaced by a light absorber to absorb the concentrated light source rays 18 and convert it directly to heat for transfer to a desired application. The desired application can vary from domestic hot water, water purification, commercial processing, or absorption air conditioning. The heat can also be used directly to: (1) drive heat engines such as Stirling engines; (2) super heat steam to drive a steam engine or turbine; (3) to fuel a thermal electric generator; or (4) drive any other type of thermal engine or heat application.

The foregoing has constituted a description of specific embodiments. These embodiments are only exemplary. The concentrated photovoltaic and thermal system in its broadest, and more specific aspects, is further described and defined in the claims which now follow.

What is claimed is:

1. A concentrated photovoltaic solar collector comprising:
a) a housing having an upper opening and a lower opening, where the lower opening is narrower than the upper opening;
b) a solar cell positioned at the lower opening of the housing;
c) a primary optical element positioned proximate to the upper opening of the housing; and
d) a secondary optical element positioned inside the housing and proximate to the lower opening;
wherein the primary optical element and the secondary optical element are shaped, dimensioned and positioned to direct and concentrate light source rays into the housing and onto the solar cell.

2. The concentrated photovoltaic solar collector according to claim 1, wherein the shape of the housing is an inverted symmetrical, truncated, pyramid.

3. The concentrated photovoltaic solar collector according to claim 1 or 2, wherein the primary optical element is a Fresnel lens.

4. The concentrated photovoltaic solar collector according to any one of claims 1 to 3, wherein the secondary optical element is a continuous hollow structure having an entry aperture and an exit aperture, and comprising a reflective interior surface.

5. The concentrated photovoltaic solar collector according to claim 4, wherein the secondary optical element has a first side having a first slope, and a second side having a second slope.

6. The concentrated photovoltaic solar collector according to claim 4 or 5, wherein the secondary optical element comprises an optical material having an index of refraction greater than air, positioned between the entry and exit apertures.

7. The concentrated photovoltaic solar collector according to any one of claims 1 to 6, wherein the inner surface of the housing is reflective.

8. A concentrated photovoltaic solar collector system comprising:
a) at least one concentrated photovoltaic receiver assembly, the concentrated photovoltaic receiver assembly comprising:
i) the solar collector as defined in any one of claims 1 to 7;
ii) a thermal conversion device in thermal communication with the solar cell; and
iii) a cooling unit in thermal communication with the thermal conversion device and/or the solar cell; and
b) a sun tracking system that provides support and movement to at least one concentrated photovoltaic receiver assembly.

9. The concentrated photovoltaic collector system according to claim 8, wherein the sun tracking system comprises:
a) a base;
b) a platform adapted to receive the at least one concentrated photovoltaic receiver assembly; and
c) a plurality of linear actuators movably connecting the platform to the base;
wherein the plurality of linear actuators extend and retract to tilt the platform.

10. The concentrated photovoltaic collector system according to claim 9, wherein the plurality of linear actuators is connected to the platform and/or base with spherical connectors.

11. The concentrated photovoltaic collector system according to any one of claims 8 to 10, wherein the cooling unit circulates coolant above and below the electromagnetic energy receiver.

12. The concentrated photovoltaic collector system according to claim 11, wherein the electromagnetic energy receiver has a transparent coating to prevent the coolant from directly contacting the electromagnetic energy receiver.

13. The concentrated photovoltaic collector system according to claim 12, wherein the electromagnetic energy receiver has a transparent coating to prevent the coolant from directly contacting the electromagnetic energy receiver.

14. A sun tracking system comprising:
a) a base;
b) a platform adapted to receive the at least one concentrated photovoltaic receiver assembly; and
c) a plurality of linear actuators movably connecting the platform to the base;
wherein the plurality of linear actuators extend and retract to tilt the platform.

15. The sun tracking system according to claim 14, wherein the plurality of linear actuators are connected to the platform and/or base with spherical connectors.

16. The sun tracking system according to claim 14 or 15, wherein one of the plurality of linear actuators connects the base to a central portion of the platform in order to raise and lower the platform.
